(19) United States
(12) Patent Application Publication
(10) Pub. No.: US 2025/0336463 A1
(43) Pub. Date: Oct. 30, 2025

(54) ERASE VERIFY SKIP FOR FAST CYCLING

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/170,587

(22) Filed: Apr. 4, 2025

Related U.S. Application Data
(60) Provisional application No. 63/640,782, filed on Apr. 30, 2024.

(51) Int. Cl. G11C 29/38

(52) U.S. Cl. CPC G11C 29/38

(57) ABSTRACT

Methods, systems, and devices for erase verify skip for fast cycling are described. A memory device may receive a command to perform an erase operation involving a first type of erase operation excluding an erase verify operation, and may apply a pre-programming pulse and an erase pulse to a block of memory cells while skipping an erase verify operation for one or more memory cells of the block based on the command. In some examples, the memory device may skip one or more erase verify operations based one or more internal trim settings. Additionally, or alternatively, erase verify skipping may be adaptive. For example, once a quantity of erase operations satisfies a threshold quantity, the memory device may receive a second command and may perform a second erase operation involving performing an erase verify operation for one or more memory cells of the block.

### CROSS REFERENCE

The present Application for Patent claims priority to U.S. Patent Application No. 63/640,782 by Lien et al., entitled “ERASE VERIFY SKIP FOR FAST CYCLING,” filed Apr. 30, 2024, which is assigned to the assignee hereof, and which is expressly incorporated by reference in its entirety herein.

### TECHNICAL FIELD

The following relates to one or more systems for memory, including erase verify skip for fast cycling.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports erase verify skip for fast cycling in accordance with examples as disclosed herein.

FIG. 2 shows an example of a flow diagram that supports erase verify skip for fast cycling in accordance with examples as disclosed herein.

FIG. 3 shows an example of a timing diagram that supports erase verify skip for fast cycling in accordance with examples as disclosed herein.

FIG. 4 shows a block diagram of a memory system that supports erase verify skip for fast cycling in accordance with examples as disclosed herein.

FIG. 5 shows a block diagram of a host system that supports erase verify skip for fast cycling in accordance with examples as disclosed herein.

FIGS. 6 and 7 show flowcharts illustrating a method or methods that support erase verify skip for fast cycling in accordance with examples as disclosed herein.

### DETAILED DESCRIPTION

Some memory devices, including not-AND (NAND) memory devices, may support program and erase cycles (PEC), where a PEC may involve a program operation and an erase operation. Erase operations may include multiple sub-operations such as applying an erase pulse and an erase verify, while addition sub-operations may include applying a pre-program pulse, an anneal pulse, a source-gate (SG) check, among other steps. Erase operations and program operations may in some cases be used in different End of life (EOL) cycling and testing to determine an EOL performance of a device, while some EOL cycling and testing may apply operations to a subset of memory cells or omit programming operations in favor of erase operations to increase a speed in operations. However, additional techniques may be desired for improving EOL cycling speed.

As described herein, an erase scheme may skip an erase verify step to reduce a time of an erase operation. For example, a memory device may apply a pre-programming pulse and an erase pulse to a block of memory cells while skipping an erase verify operation for one or more memory cells of the block. In some cases, skipping one or more erase verify operations may be determined based on a command sequence or one or more internal NAND trim settings. Skipping may also be adaptive, where erase verify operations may be skipped for a quantity of EOL cycles (e.g., erase cycles) before reaching a threshold quantity, after which erase verify operations may resume. By skipping one or more erase verify operations, a block erase time (tBERS) may be reduced to increase a speed of erase operations, which may improve performance in operation or testing of one or more devices. Further, reducing a time required for each erase cycle may allow EOL cycling (e.g., full block EOL cycling) to be stressed faster.

In addition to applicability in memory systems as described herein, techniques for skipping erase verify for fast cycling may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein, including a new erase scheme involving at least partial skipping of erase verify, may improve a tBERS for a device, which may improve the performance of electronic devices generally and during qualification testing. Such an erase scheme may also reduce a time for EOL cycling during testing to improve production times and ability to test a greater quantity of devices in a smaller amount of time, among other benefits.

Features of the disclosure are illustrated and described in the context of systems, devices, and circuits. Features of the disclosure are further illustrated and described in the context of flow diagrams, verify diagrams, block diagrams, and flowcharts.

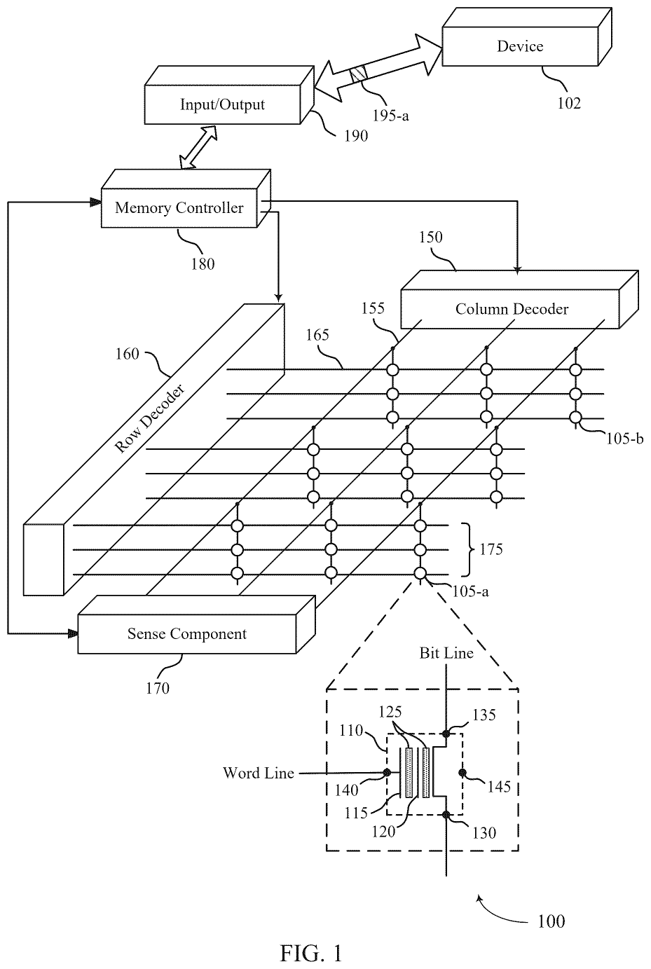

FIG. 1 shows an example of a memory device 100 that supports erase verify skip for fast cycling in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC) (e.g., triple-level cell), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105.

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some examples, the memory device 100 may include one or more blocks and sub-blocks of memory cells 105. In some examples, a block may represent a section or subset of memory cells of a single word line tier, or word line layer, of the memory device 100, where a word-line tier/layer may correspond to one of the multiple levels of bit lines 155 and word lines 165 with corresponding memory cells 105. Additionally, or alternatively, each block of memory cells 105 may include one or more sub-blocks of memory cells, where each sub-block may be a sub-set of the block. In some examples, each block, and sub-block, may be operable to be accessed independently of other blocks and sub-blocks. Additionally, or alternatively, blocks and sub-blocks of memory cells may be defined to include different sub-sets of memory cells 105 of the memory device 100 not shown.

In some cases, the memory device 100 may be coupled with one or more external devices. For example, the input/output component 190 may be coupled with a device 102 via one or more channels, pins, or other electrodes, where the device 102 may represent a host system or a testing device for one or more test operations, among other devices. In some cases, the device 102 may be operable to transmit one or more commands 195 (e.g., access commands, write/program commands, erase commands) to the memory controller 180 via the input/output component 190, including commands related to one or more test operations at the memory device 100. Additionally, or alternatively, the device 102 may represent one or more devices, components, or circuitry within the memory device 100.

As described herein, the memory device 100 may support an erase scheme that may skip an erase verify step to reduce a time of an erase operation. For example, the memory device 100 may apply a pre-programming pulse and an erase pulse to a block of memory cells 105 while skipping an erase verify operation for one or more memory cells 105 of the block. In some cases, an erase operation may be a block operation that may be performed on more than one active planes of the memory device 100. In some cases, skipping one or more erase verify operations may be determined based on a command sequence or one or more internal NAND trim settings. For example, the memory device 100 may receive a command 195-a indicating to perform one or more erase operations that may skip erase verify steps. Additionally, or alternatively, the command 195-a, or another signal, may indicate one or more NAND trim settings, or may enable one or more NAND trim settings already stored at a register of the memory device 100. In some examples, skipping erase verify may be adaptive, where erase verify operations may be skipped for a quantity of EOL cycles (e.g., erase cycles) before reaching a threshold quantity, after which erase verify operations may resume.

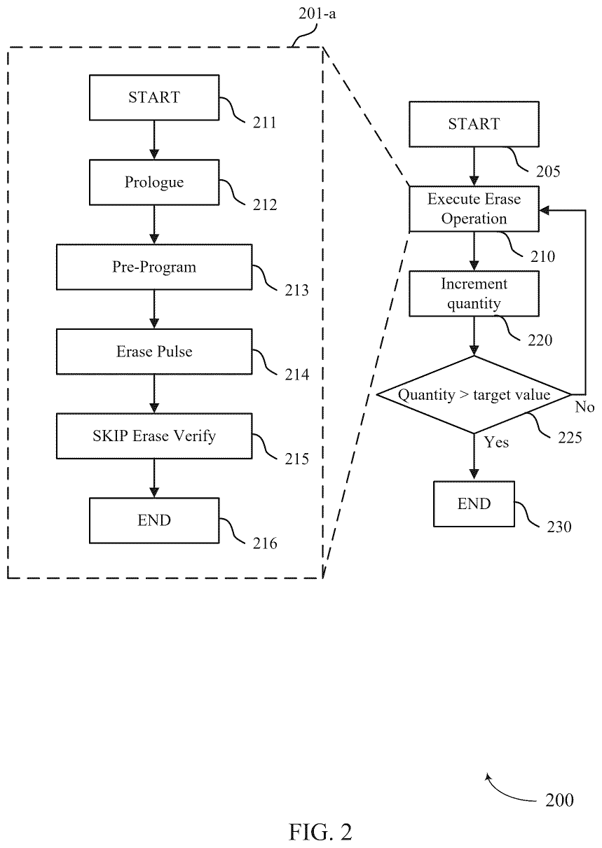

FIG. 2 shows an example of a flow diagram 200 that supports erase verify skip for fast cycling in accordance with examples as disclosed herein. One or more aspects of the flow diagram 200 may be implemented by one or more aspects of the memory device 100 as described with reference to FIG. 1. For example, flow diagram 200 may illustrate one or more sub-operations of a type of erase operation (e.g., erase scheme, erase algorithm) performed in a memory device, such as the memory device 100. In some cases, the flow diagram 200 may illustrate system usage of one or more steps, including using an erase scheme 201-a that may support skipping erase verify operations for one or more memory cells.

Some memory devices may support PECs. For example, during a PEC, a memory device (e.g., a NAND memory device) may perform a program operation including one or more sub-operations. When a memory device performs a program operation, the memory device may in some cases use a program verify operation after applying a program pulse to one or more memory cells to check if each memory cell of the program operation is programmed correctly. An erase operation of the PEC may similarly include various sub-operations (e.g., phases) within an overall erase operation. For example, different types of erase operations, such as different erase schemes 201 (e.g., algorithms), may include basic elements such as an erase pulse and an erase verify, among additional sub-operations including a pre-program, an anneal pulse, and an SG check, among other sub-operations (e.g., algorithm validation). An erase verify operation may in some cases include determining whether one or more memory cells are fully erased when one or more erase pulses are applied to the one or more memory cells. In some cases, if a memory device determines that a subset of the one or more memory cells are not fully erased based on performing an erase verify operation, one or more additional erase pulses may be applied to the subset or to the one or more memory cells.

In some cases, one or more operations in PECs may be omitted during EOL cycling to increase a speed of testing. For example, EOL cycling (e.g., full drive EOL cycling) may involve testing and measuring EOL performance and latency of a memory device. In some cases, a “short stroke” case may be used, which may indicate performing cycling on a subset (e.g., a percentage) of blocks of a drive (e.g., of the memory device). A short stroke case and associated measurements may provide different results from a “full stroke” case (e.g., measuring each block of the drive or memory device). Short stroke testing may reduce test time, but may apply to consecutive blocks (e.g., due to firmware limitations) which may induce systematic bias, and may further involve over provision percentage, garbage collection, firmware management, among other processes. Short stroke cycling may also be destructive (e.g., may render a die or memory device unusable). Additionally, or alternatively, a fast cycling approach may be applied that may involve omitting one or more steps, or all steps, of program operations of PEC cycles in EOL testing to instead focus on performing erase operations and reduce a time to perform EOL testing. Fast cycling may also include raising a pre-program voltage and erase voltage within a type of erase operation and applying a corresponding erase count to match a normal cycling at various reliability corners. Fast cycling may in some cases be performed on a sacrificial block of cells and may be non-destructive to an entire memory device. In some examples, however, there may exist additional opportunities to further reduce a time to perform EOL cycling and testing, even when using fast cycling methods.

As described herein, the flow diagram 200 may illustrate a type of erase operation that may include a pre-program and erase pulse but without an erase verify, which may be used to achieve full drive EOL fast cycling. In some examples, in the following description of the flow diagram 200, the operations may be performed (such as reported or provided) in a different order than the order shown, or the operations performed by the example devices may be performed in different orders or at different times. Some operations also may be omitted from the flow diagram 200, or other operations may be added to the flow diagram 200. Further, although some operations or signaling may be shown to occur at different times for discussion purposes, these operations may actually occur at the same time or at least partially concurrently.

At 205, EOL cycling, such as EOL fast cycling, may be begin. For example, a memory device may receive one or more commands and may perform EOL fast cycling in response to the commands. The EOL fast cycling may include performing a quantity of EOL cycles at 210. In some examples, an erase scheme 201-a, which may be a first type of erase operation performed at 210, may be illustrated by one or more sub-operations. For example, the erase scheme 201-a may include a start or beginning of an erase operation at 211 and a prologue at 212. During the prologue, the memory device may perform one or more calculations associated with later sub-operations, including determining timing, bias values (e.g., voltages, currents), among other parameters. At 213, the memory device may perform a pre-program including applying a pre-programming pulse to each memory cell of a block of memory cells. A pre-program pulse may in some cases be different than a program pulse as a pre-program pulse may be applied to each word line of each sub-block of the block (for which the erase operation is performed) at a same time, compared to performing a program word line by word line. At 214, the memory device may perform an erase by applying an erase pulse to each of the memory cells of the block.

The erase scheme 201-a may exclude an erase verify operation. For example, at 215 the memory device may exclude, or skip, an erase verify operation for one or more cells of the block based on the erase operation being the erase scheme 201-a. In some cases, the erase scheme 201-a may involve a partial skip verify, where a partial skip verify may indicate that erase verify operations for one or more subsets of memory cells are skipped. For example, a combination of sub-blocks or word lines (e.g., even word lines, odd word lines) of memory cell erase verify operations may be skipped (e.g., either some sub-blocks or either odd or even verifies are skipped). Odd and even word lines may refer to even numbered or odd numbered alternating word lines. For example, in a first erase operation, the memory device may perform erase verify for odd word lines of a first sub-block (e.g., SB0) of a block while skipping erase verify operations for a remainder of memory cells of the block. Additionally, or alternatively, each erase verify may be performed for alternative (or alternating) odd word lines of a first sub-block (e.g., SB0), alternative even word lines of the first sub-block, alternative odd word lines of a second sub-block (e.g., SB1), and so on (e.g., in some cases, using a different combination during each erase operation). The memory device may also apply one or more additional erase pulses if one or more erase verify operations fail. After performing the one or more erase verify operations, the erase scheme 201-a may end at 216.

After performing the erase operation according to the erase scheme 201-a, a determination may be made whether a target or threshold is met. For example, after performing the erase operation according to the erase scheme 201-a, a quantity (e.g., counter) of PECs, or in this case a quantity of erase operations as each PEC may omit a program, may be incremented (e.g., PEC=PEC+1) at 220, and may be compared to a target value or threshold (e.g., PEC_{target}) at 225. If the quantity does not satisfy (e.g., is less than, is less than or equal to) the target value, the memory device may return to 210 to perform another erase operation. Otherwise, if the counter satisfies (e.g., is greater than, is greater than or equal to) the target value, the memory device 100 may end EOL cycling at 230. The target value may be determined by the memory device or may be indicated by an external device (e.g., the device 102). In some cases, the determination at 225 may be performed by the memory device. For example, the memory device may receive a single command to perform EOL cycling, and may perform erase operations until the memory device determines that the target value is met or exceeded. Additionally, or alternatively, the determination at 225 may be performed by an external device (e.g., the device 102).

In some examples, the erase scheme 201-a may be controlled by a new command sequence. For example, the memory device may receive a command sequence to perform an erase operation according to the first type of erase operation, or the erase scheme 201-a, and may perform the erase operation according to the erase scheme 201-a including all sub-operations. The command sequence may indicate the erase scheme 201-a, as well as may indicate one or more subsets of memory cells (e.g., sub-blocks, even word lines, odd word lines) for which to skip erase verify operations, or to skip erase verify operations for all memory cells of a block. Additionally, or alternatively, the memory device may receive a second command sequence that may indicate to perform a different erase scheme 201 (e.g., an erase scheme that includes an erase verify operation for all memory cells of a block). Additionally, or alternatively, one or more fields in one or more commands may be defined or reused to indicate trim settings, schemes or erase operations (or other operation, such as both erase and program schemes), etc.

Additionally, or alternatively, the erase scheme 201-a may be controlled by one or more internal parameters or settings. For example, the memory device may store one or more internal NAND trim settings (e.g., written to a register of the memory device) that may indicate different parameters for one or more schemes 201. The trim settings may, for example, indicate one or more sub-sets of memory cells, one or more currents or voltages (e.g., erase voltages, program/write voltages, pre-program voltages, read voltages) that may be the same or different than other operating currents or voltages (e.g., increased in fast cycling compared to normal cycling operations), among other parameters. In some cases, the trim settings may be indicated by one or more signals or commands, while the voltages may be internally generated by the memory device and may correspond to a test condition. In some examples, one or more commands received from an external device (e.g., the device 102) may enable or disable one or more trim settings (e.g., commands to perform erase operations), where the memory device may perform an erase scheme 201-a or other erase scheme 201, or sub-operations for one or more erase schemes, based on which trim settings are enabled. Erase verify operations may be skipped for one or more of normal cycling operations (e.g., including program operations) or fast cycling operations (e.g., EOL cycling that may omit program operations). For example, normal cycling may skip erase verify for quantities of PECs below a PEC threshold, but may include erase verify above the PEC threshold. Fast cycling operations may also skip erase verify for one or more memory cells based on an increased pre-programming voltage (V_{ppgm}), an increased erase voltage (V_{ERA}), a constant or relatively stable erase time (e.g., tBERS), or any combination thereof for one or more blocks or logical units.

In some examples, the erase scheme 201-a may include additional operations, such as an anneal pulse, an SG check, any combination of partial and full erase verify operations, program operations (e.g., including applying a programming pulse to one or more memory cells of a block), among other operations. Further, although the pre-program may occur prior to the erase pulse in FIG. 2, a pre-program pulse may be applied either before or after an erase pulse. Additionally, or alternatively, any combination of sub-sets of memory cells (e.g., word lines, planes, sub-blocks) may be used for erase verify operations or to skip erase verify operations. Erase schemes 201, such as the erase scheme 201-a, may also be applied to any bit per cell (BPC) (e.g., SLC, MLC, TLC, QLC) where each BPC may have a corresponding erase scheme. The operations described herein may also be applied to different types of non-volatile memory, including NAND memory, resistive random access memory (Re-RAM) memory, phase change memory (PCM), among other memory if involving an erase operation and EOL cycling evaluation (e.g., full block EOL cycling evaluation). Additionally, or alternatively, the operations described herein (e.g., skipping erase verify) may be involved in one or more testing operations or non-testing operations at a memory device (e.g., for one or more memory dies), and may be destructive or non-destructive (e.g., with a sacrificial block), and for one or more memory blocks.

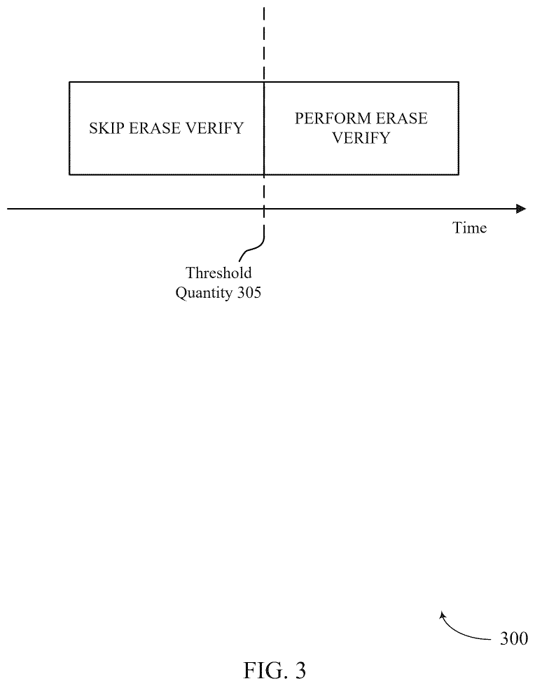

FIG. 3 shows an example of a timing diagram 300 that supports erase verify skip for fast cycling in accordance with examples as disclosed herein. One or more aspects of the timing diagram 300 may be implemented by one or more aspects of the memory device 100 and the flow diagram 200 as described with reference to FIGS. 1 and 2. For example, the timing diagram 300 may illustrate timing for performing one or more erase operations for a block of memory cells based on receiving one or more commands. In some cases, the timing diagram 300 may illustrate an adaptive skip erase verify for one or more erase operations.

For example, a memory device may perform EOL cycling, including EOL cycling with both program and erase operations, or EOL fast cycling including erase operations. During one or more EOL cycles (e.g., PEC, program and erase operation, erase operation), the memory device may skip erase verify operations for one or more memory cells as described herein. In some examples, the memory device may skip the erase verify operations if a quantity of operations (e.g., PECs, erase and program operations, erase operations) is less than a threshold quantity 305, where the threshold quantity 305 (e.g., PEC_{threshold}) may represent a threshold quantity of operations (e.g., PECs, erase and program operations, erase operations). Once the quantity of operations satisfies the threshold quantity 305, the memory device may resume erase verify operations for one or more memory cells or for each memory cell of a block. Such operations may involve different types of erase operations (e.g., schemes 201). For example, while under the threshold quantity 305, the memory device may receive one or more commands to perform erase operations according to a first type of erase operation (e.g., the erase scheme 201-a) for skipping one or more erase verify operations, and may receive one or more commands to perform erase operations according to a second type of erase operation for performing one or more erase verify operations once the threshold quantity 305 is satisfied. In some examples, skipping one or more erase verify operations as described in FIGS. 1-3 may reduce an erase time, or tBERS, at a memory device. Further, by skipping erase verify operations for one or more memory cells, full block EOL cycling (e.g., involving a full block) may be further stressed faster.

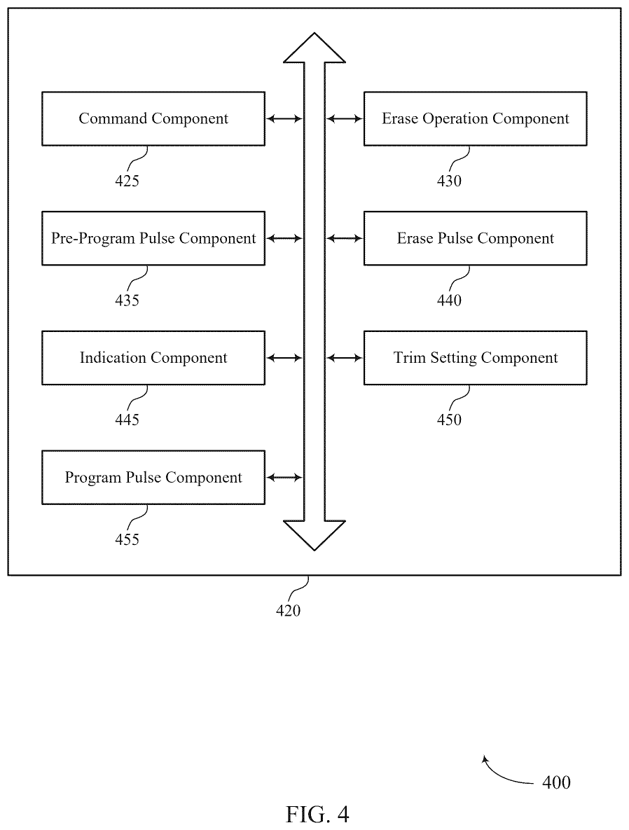

FIG. 4 shows a block diagram 400 of a memory system 420 that supports erase verify skip for fast cycling in accordance with examples as disclosed herein. The memory system 420 may be an example of aspects of a memory system as described with reference to FIGS. 1 through 3. The memory system 420, or various components thereof, may be an example of means for performing various aspects of erase verify skip for fast cycling as described herein. For example, the memory system 420 may include a command component 425, an erase operation component 430, a pre-program pulse component 435, an erase pulse component 440, an indication component 445, a trim setting component 450, a program pulse component 455, or any combination thereof. Each of these components, or components of subcomponents thereof (e.g., one or more processors, one or more memories), may communicate, directly or indirectly, with one another (e.g., via one or more buses).

The command component 425 may be configured as or otherwise support a means for receiving a command to perform an erase operation, where the erase operation is one of a set of erase operations, the set of erase operations including a first type of erase operation that excludes an erase verify operation for one or more memory cells of a block of memory cells and a second type of erase operation that includes the erase verify operation for each memory cell of the block. The erase operation component 430 may be configured as or otherwise support a means for performing the erase operation based at least in part on the command. The pre-program pulse component 435 may be configured as or otherwise support a means for applying a pre-programming pulse to each memory cell of the block of memory cells. The erase pulse component 440 may be configured as or otherwise support a means for applying an erase pulse to each memory cell of the block of memory cells. In some examples, the erase operation component 430 may be configured as or otherwise support a means for excluding the erase verify operation for one or more memory cells of the block based at least in part on the erase operation being the first type of erase operation. In some cases, performing the erase operation may include applying the pre-programming pulse, applying the erase pulse, and excluding the erase verify operation.

In some examples, to support excluding the erase verify operation for one or more memory cells of the block, the erase operation component 430 may be configured as or otherwise support a means for excluding the erase verify operation for one or more memory cells of one or more odd access lines, for one or more memory cells of one or more even access lines, for one or more memory cells of one or more subblocks, or any combination thereof.

In some examples, the command component 425 may be configured as or otherwise support a means for receiving, within the command, an indication to perform the first type of erase operation, where performing the erase operation is based at least in part on the indication.

In some examples, the indication component 445 may be configured as or otherwise support a means for receiving an indication to enable one or more trim settings associated with the first type of erase operation that are stored at the memory device. In some examples, the trim setting component 450 may be configured as or otherwise support a means for enabling the one or more trim settings based at least in part on the indication, where performing the first type of erase operation is based at least in part on enabling the one or more trim settings.

In some examples, the erase operation component 430 may be configured as or otherwise support a means for performing a second erase operation of the set of erase operations, where performing the second erase operation includes performing the erase verify operation for the one or more memory cells of the block based at least in part on the second erase operation being the second type of erase operation.

In some examples, performing the second erase operation is based at least in part on a quantity of erase operations including the erase operation satisfying a threshold quantity of erase operations.

In some examples, the command component 425 may be configured as or otherwise support a means for receiving a second command to perform the second erase operation of the set of erase operations, where performing the second erase operation is based at least in part on the second command.

In some examples, the indication component 445 may be configured as or otherwise support a means for receiving an indication of a respective voltage for the pre-programming pulse and a respective voltage for the erase pulse for the erase operation.

In some examples, a respective voltage for each of the pre-programming pulse and the erase pulse of the erase operation is greater than a respective second voltage for each of a pre-programming pulse and an erase pulse of a second erase operation that is the second type of erase operation.

In some examples, to support performing the erase operation, the program pulse component 455 may be configured as or otherwise support a means for applying a programming pulse to one or more memory cells of the block of memory cells, applying an anneal pulse to one or more memory cells of the block, performing an SG check for one or more memory cells of the block, or any combination thereof.

In some examples, the pre-programming pulse is applied before the erase pulse. In some examples, the pre-programming pulse is applied after the erase pulse. In some examples, a time duration associated with performing the erase operation is less than a time duration associated with performing a second erase operation that is the second type of erase operation. In some examples, each memory cell of the block of memory cells is configured to store information according to an SLC operation, an MLC operation, a TLC operation, or a QLC operation. In some examples, the block of memory cells includes one or more NAND memory cells, one or more Re-RAM memory cells, one or more PCM memory cells, or any combination thereof.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

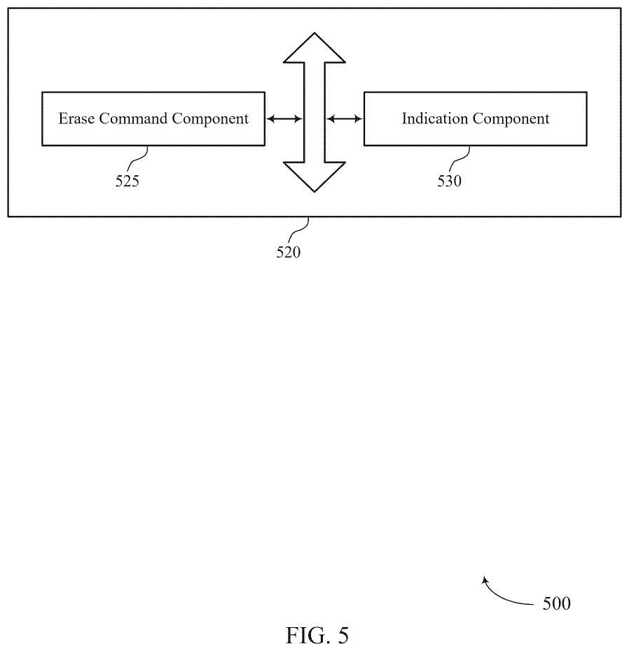

FIG. 5 shows a block diagram 500 of a host system 520 that supports erase verify skip for fast cycling in accordance with examples as disclosed herein. The host system 520 may be an example of aspects of a host system as described with reference to FIGS. 1 through 3. The host system 520, or various components thereof, may be an example of means for performing various aspects of erase verify skip for fast cycling as described herein. For example, the host system 520 may include an erase command component 525 an indication component 530, or any combination thereof. Each of these components, or components of subcomponents thereof (e.g., one or more processors, one or more memories), may communicate, directly or indirectly, with one another (e.g., via one or more buses).

The erase command component 525 may be configured as or otherwise support a means for transmitting a first plurality of erase commands to perform a plurality of first erase operations of a set of erase operations, where the plurality of first erase operations are of a first type of erase operation that excludes an erase verify operation. In some examples, the erase command component 525 may be configured as or otherwise support a means for transmitting a second plurality of erase commands to perform a plurality of second erase operations of the set of erase operations, where the plurality of second erase operations are of a second type of erase operation that includes the erase verify operation.

In some examples, the erase command component 525 may be configured as or otherwise support a means for transmitting, within the first plurality of erase commands, an indication to perform the first type of erase operation.

In some examples, the indication component 530 may be configured as or otherwise support a means for transmitting, prior to transmitting the first plurality of erase commands, an indication to enable one or more trim settings associated with the first type of erase operation that excludes the erase verify operation.

In some examples, transmitting the second plurality of erase commands is based at least in part on a quantity of erase operations including the plurality of first erase operations satisfying a threshold quantity of erase operations.

In some examples, the indication component 530 may be configured as or otherwise support a means for transmitting an indication of a respective voltage for a pre-programming pulse and a respective voltage for an erase pulse for the plurality of first erase operations.

In some examples, a respective voltage for each of a pre-programming pulse and an erase pulse of the plurality of first erase operations is greater than a respective second voltage for each of a pre-programming pulse and an erase pulse of the plurality of second erase operations.

In some examples, the described functionality of the host system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 520, or various components thereof, may be implemented at least in part by instructions (e.g., stored in memory, non-transitory computer-readable medium) executable by such at least one processor.

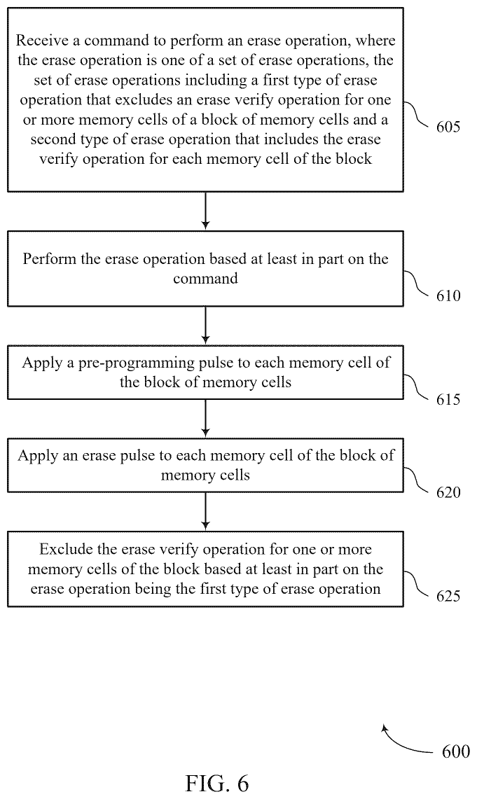

FIG. 6 shows a flowchart illustrating a method 600 that supports erase verify skip for fast cycling in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include receiving a command to perform an erase operation, where the erase operation is one of a set of erase operations, the set of erase operations including a first type of erase operation that excludes an erase verify operation for one or more memory cells of a block of memory cells and a second type of erase operation that includes the erase verify operation for each memory cell of the block. In some examples, aspects of the operations of 605 may be performed by a command component 425 as described with reference to FIG. 4.

At 610, the method may include performing the erase operation based at least in part on the command. In some examples, aspects of the operations of 610 may be performed by an erase operation component 430 as described with reference to FIG. 4. In some cases, performing the erase operation may include the steps performed at 615, 620, and 625.

At 615, the method may include applying a pre-programming pulse to each memory cell of the block of memory cells. In some examples, aspects of the operations of 615 may be performed by a pre-program pulse component 435 as described with reference to FIG. 4.

At 620, the method may include applying an erase pulse to each memory cell of the block of memory cells. In some examples, aspects of the operations of 620 may be performed by an erase pulse component 440 as described with reference to FIG. 4.

At 625, the method may include excluding the erase verify operation for one or more memory cells of the block based at least in part on the erase operation being the first type of erase operation. In some examples, aspects of the operations of 625 may be performed by an erase operation component 430 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a command (e.g., a command 195) to perform an erase operation, where the erase operation is one of a set of erase operations, the set of erase operations including a first type of erase operation (e.g., the erase scheme 201-a) that excludes an erase verify operation for one or more memory cells of a block of memory cells and a second type of erase operation (e.g., a second erase scheme 201) that includes the erase verify operation for each memory cell of the block; performing the erase operation (e.g., at 210) based at least in part on the command, where performing the erase operation includes; applying a pre-programming pulse (e.g., at 213) to each memory cell of the block of memory cells; applying an erase pulse (e.g., at 214) to each memory cell of the block of memory cells; and excluding the erase verify operation (e.g., at 215) for one or more memory cells of the block based at least in part on the erase operation being the first type of erase operation.

Aspect 2: The method, apparatus, or non-transitory computer-readable medium of aspect 1, where excluding the erase verify operation for one or more memory cells of the block includes operations, features, circuitry, logic, means, or instructions, or any combination thereof for excluding the erase verify operation for one or more memory cells of one or more odd access lines, for one or more memory cells of one or more even access lines, for one or more memory cells of one or more subblocks, or any combination thereof.

Aspect 3: The method, apparatus, or non-transitory computer-readable medium of any of aspects 1 through 2, further including operations, features, circuitry, logic, means, or instructions, or any combination thereof for receiving, within the command, an indication to perform the first type of erase operation, where performing the erase operation is based at least in part on the indication.

Aspect 4: The method, apparatus, or non-transitory computer-readable medium of any of aspects 1 through 3, further including operations, features, circuitry, logic, means, or instructions, or any combination thereof for receiving an indication to enable one or more trim settings associated with the first type of erase operation that are stored at the memory device and enabling the one or more trim settings based at least in part on the indication, where performing the first type of erase operation is based at least in part on enabling the one or more trim settings.

Aspect 5: The method, apparatus, or non-transitory computer-readable medium of any of aspects 1 through 4, further including operations, features, circuitry, logic, means, or instructions, or any combination thereof for performing a second erase operation of the set of erase operations, where performing the second erase operation includes performing the erase verify operation for the one or more memory cells of the block based at least in part on the second erase operation being the second type of erase operation (e.g., a second erase scheme 201).

Aspect 6: The method, apparatus, or non-transitory computer-readable medium of aspect 5, where performing the second erase operation is based at least in part on a quantity of erase operations including the erase operation satisfying a threshold quantity of erase operations (e.g., PEC_{threshold}).

Aspect 7: The method, apparatus, or non-transitory computer-readable medium of any of aspects 5 through 6, further including operations, features, circuitry, logic, means, or instructions, or any combination thereof for receiving a second command to perform the second erase operation of the set of erase operations, where performing the second erase operation is based at least in part on the second command.

Aspect 8: The method, apparatus, or non-transitory computer-readable medium of any of aspects 1 through 7, further including operations, features, circuitry, logic, means, or instructions, or any combination thereof for receiving an indication of a respective voltage for the pre-programming pulse and a respective voltage for the erase pulse for the erase operation.

Aspect 9: The method, apparatus, or non-transitory computer-readable medium of any of aspects 1 through 8, where a respective voltage for each of the pre-programming pulse and the erase pulse of the erase operation is greater than a respective second voltage for each of a pre-programming pulse and an erase pulse of a second erase operation that is the second type of erase operation.

Aspect 10: The method, apparatus, or non-transitory computer-readable medium of any of aspects 1 through 9, where performing the erase operation further includes operations, features, circuitry, logic, means, or instructions, or any combination thereof for applying a programming pulse to one or more memory cells of the block of memory cells, applying an anneal pulse to one or more memory cells of the block, performing an SG check for one or more memory cells of the block, or any combination thereof.

Aspect 11: The method, apparatus, or non-transitory computer-readable medium of any of aspects 1 through 10, where the pre-programming pulse is applied before the erase pulse.

Aspect 12: The method, apparatus, or non-transitory computer-readable medium of any of aspects 1 through 11, where the pre-programming pulse is applied after the erase pulse.

Aspect 13: The method, apparatus, or non-transitory computer-readable medium

of any of aspects 1 through 12, where a time duration associated with performing the erase operation is less than a time duration associated with performing a second erase operation that is the second type of erase operation (e.g., speed of EOL cycling is increased).

Aspect 14: The method, apparatus, or non-transitory computer-readable medium of any of aspects 1 through 13, where each memory cell of the block of memory cells is configured to store information according to an SLC operation, an MLC operation, a TLC operation, or a QLC operation.

Aspect 15: The method, apparatus, or non-transitory computer-readable medium of any of aspects 1 through 14, where the block of memory cells includes one or more NAND memory cells, one or more Re-RAM memory cells, one or more PCM cells, or any combination thereof.

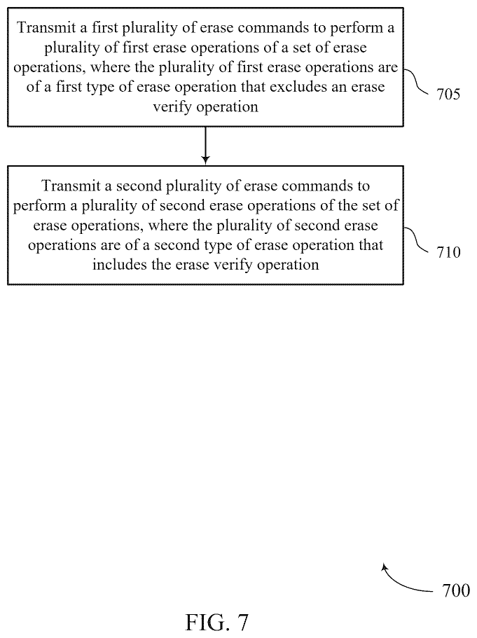

FIG. 7 shows a flowchart illustrating a method 700 that supports erase verify skip for fast cycling in accordance with examples as disclosed herein. The operations of method 700 may be implemented by a host system or its components as described herein. For example, the operations of method 700 may be performed by a host system as described with reference to FIGS. 1 through 3 and 5. In some examples, a host system may execute a set of instructions to control the functional elements of the device to perform the described functions. Additionally, or alternatively, the host system may perform aspects of the described functions using special-purpose hardware.

At 705, the method may include transmitting a first plurality of erase commands to perform a plurality of first erase operations of a set of erase operations, where the plurality of first erase operations are of a first type of erase operation that excludes an erase verify operation. In some examples, aspects of the operations of 705 may be performed by an erase command component 525 as described with reference to FIG. 5.

At 710, the method may include transmitting a second plurality of erase commands to perform a plurality of second erase operations of the set of erase operations, where the plurality of second erase operations are of a second type of erase operation that includes the erase verify operation. In some examples, aspects of the operations of 710 may be performed by an erase command component 525 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 16: A method, apparatus, or non-transitory computer-readable medium including operations, features, circuitry, logic, means, or instructions, or any combination thereof for transmitting (e.g., from the device) a first plurality of erase commands (e.g., a first set of commands) to perform a plurality of first erase operations of a set of erase operations, where the plurality of first erase operations are of a first type of erase operation (e.g., the erase scheme) that excludes an erase verify operation and transmitting a second plurality of erase commands (e.g., a second set of commands) to perform a plurality of second erase operations of the set of erase operations, where the plurality of second erase operations are of a second type of erase operation (e.g., a second erase scheme) that includes the erase verify operation.

Aspect 17: The method, apparatus, or non-transitory computer-readable medium of aspect 16, further including operations, features, circuitry, logic, means, or instructions, or any combination thereof for transmitting, within the first plurality of erase commands, an indication to perform the first type of erase operation.

Aspect 18: The method, apparatus, or non-transitory computer-readable medium of any of aspects 16 through 17, further including operations, features, circuitry, logic, means, or instructions, or any combination thereof for transmitting, prior to transmitting the first plurality of erase commands, an indication to enable one or more trim settings associated with the first type of erase operation that excludes the erase verify operation.

Aspect 19: The method, apparatus, or non-transitory computer-readable medium of any of aspects 16 through 18, where transmitting the second plurality of erase commands is based at least in part on a quantity of erase operations including the plurality of first erase operations satisfying a threshold quantity of erase operations.

Aspect 20: The method, apparatus, or non-transitory computer-readable medium of any of aspects 16 through 19, further including operations, features, circuitry, logic, means, or instructions, or any combination thereof for transmitting an indication of a respective voltage for a pre-programming pulse and a respective voltage for an erase pulse for the plurality of first erase operations.

Aspect 21: The method, apparatus, or non-transitory computer-readable medium of aspect 20, where a respective voltage for each of a pre-programming pulse and an erase pulse of the plurality of first erase operations is greater than a respective second voltage for each of a pre-programming pulse and an erase pulse of the plurality of second erase operations.

It should be noted that the described methods include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
one or more memory arrays; and
processing circuitry coupled with the one or more memory arrays and configured to cause the memory device to:
receive a command to perform an erase operation, wherein the erase operation is one of a set of erase operations, the set of erase operations comprising a first type of erase operation that excludes an erase verify operation for one or more memory cells of a block of memory cells and a second type of erase operation that includes the erase verify operation for each memory cell of the block; and
perform the erase operation based at least in part on the command, wherein performing the erase operation comprises:
apply a pre-programming pulse to each memory cell of the block of memory cells;
apply an erase pulse to each memory cell of the block of memory cells; and
exclude the erase verify operation for one or more memory cells of the block based at least in part on the erase operation being the first type of erase operation.

2. The memory device of claim 1, wherein excluding the erase verify operation for one or more memory cells of the block comprises the processing circuitry configured to cause the memory device to:
exclude the erase verify operation for one or more memory cells of one or more odd access lines, for one or more memory cells of one or more even access lines, for one or more memory cells of one or more subblocks, or any combination thereof.

3. The memory device of claim 1, wherein the processing circuitry is further configured to cause the memory device to:
receive, within the command, an indication to perform the first type of erase operation, wherein performing the erase operation is based at least in part on the indication.

4. The memory device of claim 1, wherein the processing circuitry is further configured to cause the memory device to:
receive an indication to enable one or more trim settings associated with the first type of erase operation that are stored at the memory device; and
enable the one or more trim settings based at least in part on the indication, wherein performing the first type of erase operation is based at least in part on enabling the one or more trim settings.

5. The memory device of claim 1, wherein the processing circuitry is further configured to cause the memory device to:
perform a second erase operation of the set of erase operations, wherein performing the second erase operation includes performing the erase verify operation for the one or more memory cells of the block based at least in part on the second erase operation being the second type of erase operation.

6. The memory device of claim 5, wherein performing the second erase operation is based at least in part on a quantity of erase operations comprising the erase operation satisfying a threshold quantity of erase operations.

7. The memory device of claim 5, wherein the processing circuitry is further configured to cause the memory device to:
receive a second command to perform the second erase operation of the set of erase operations, wherein performing the second erase operation is based at least in part on the second command.

8. The memory device of claim 1, wherein the processing circuitry is further configured to cause the memory device to:
receive an indication of a respective voltage for the pre-programming pulse and a respective voltage for the erase pulse for the erase operation.

9. The memory device of claim 1, wherein a respective voltage for each of the pre-programming pulse and the erase pulse of the erase operation is greater than a respective second voltage for each of a pre-programming pulse and an erase pulse of a second erase operation that is the second type of erase operation.

10. The memory device of claim 1, wherein performing the erase operation further comprises the processing circuitry configured to cause the memory device to:
apply a programming pulse to one or more memory cells of the block of memory cells, applying an anneal pulse to one or more memory cells of the block, performing a source-gate (SG) check for one or more memory cells of the block, or any combination thereof.

11. The memory device of claim 1, wherein the pre-programming pulse is applied before the erase pulse.

12. The memory device of claim 1, wherein the pre-programming pulse is applied after the erase pulse.

13. The memory device of claim 1, wherein a time duration associated with performing the erase operation is less than a time duration associated with performing a second erase operation that is the second type of erase operation.

14. The memory device of claim 1, wherein each memory cell of the block of memory cells is configured to store information according to a single level cell (SLC) operation, a multiple-level cell (MLC) operation, a triple-level cell (TLC) operation, or a quad-level cell (QLC) operation.

15. The memory device of claim 1, wherein the block of memory cells comprises one or more not-AND (NAND) memory cells, one or more resistive random access memory (Re-RAM) memory cells, one or more phase change memory (PCM) memory cells, or any combination thereof.

16. A device, comprising:
processing circuitry associated with one or more memory devices and configured to cause the device to:
transmit a first plurality of erase commands to perform a plurality of first erase operations of a set of erase operations, wherein the plurality of first erase operations are of a first type of erase operation that excludes an erase verify operation; and
transmit a second plurality of erase commands to perform a plurality of second erase operations of the set of erase operations, wherein the plurality of second erase operations are of a second type of erase operation that comprises the erase verify operation.

17. The device of claim 16, wherein the processing circuitry is further configured to cause the device to:
transmit, within the first plurality of erase commands, an indication to perform the first type of erase operation.

18. The device of claim 16, wherein the processing circuitry is further configured to cause the device to:
transmit, prior to transmitting the first plurality of erase commands, an indication to enable one or more trim settings associated with the first type of erase operation that excludes the erase verify operation.

19. The device of claim 16, wherein transmitting the second plurality of erase commands is based at least in part on a quantity of erase operations comprising the plurality of first erase operations satisfying a threshold quantity of erase operations.

20. The device of claim 16, wherein the processing circuitry is further configured to cause the device to:
transmit an indication of a respective voltage for a pre-programming pulse and a respective voltage for an erase pulse for the plurality of first erase operations.

21. The device of claim 20, wherein a respective voltage for each of a pre-programming pulse and an erase pulse of the plurality of first erase operations is greater than a respective second voltage for each of a pre-programming pulse and an erase pulse of the plurality of second erase operations.

22. A method by a memory device, comprising:
receiving a command to perform an erase operation, wherein the erase operation is one of a set of erase operations, the set of erase operations comprising a first type of erase operation that excludes an erase verify operation for one or more memory cells of a block of memory cells and a second type of erase operation that includes the erase verify operation for each memory cell of the block; and
performing the erase operation based at least in part on the command, wherein performing the erase operation comprises:
applying a pre-programming pulse to each memory cell of the block of memory cells;
applying an erase pulse to each memory cell of the block of memory cells; and
excluding the erase verify operation for one or more memory cells of the block based at least in part on the erase operation being the first type of erase operation.
